(19) United States
(12) Patent Application Publication
(10) Pub. No.: US 2007/0000534 A1
(43) Pub. Date: Jan. 4, 2007

(54) UltraHigh Current Flow UltraHigh Surface Area ThermoCouple And Low Current Flow Junction Defeater

(75) Inventor: Lawrence Alger Cronce, Stevens Point, WI (US)

Correspondence Address: Mr.Lawrence Alger Cronce, 5139 Hwy 66, Stevens Point, WI, 54481, US

(73) Assignees: NANOSECOND TECHNOLOGIES INCORPORATED, Stevens Point, WI (US); PECIOSECOND TECHNOLOGIES CORPORATION, Stevens Point, WI (US)

(21) Appl. No.: 11/162,231

(22) Filed: Sep. 2, 2005

Related U.S. Application Data
(60) Provisional application No. 60/595,419, filed on Jul. 1, 2005.

(51) Int. Cl. H01L 35/00

(52) U.S. Cl. 136/200

(57) ABSTRACT

The UltraHigh Current Flow UltraHigh Surface Area ThermoCouple And Low Current Flow Junction Defeater is based on the fact that electricity only primarily travels on the surface of an conductor, allowing microetching of bimetallic layers and TriMetallic layers to make incredibly energy dense heating and cooling thermocouples, as well as allowing for modules for varister replacement and allowing the connection of any two types of metals without an junction voltage drop at reasonable current and voltage parameters.

The Design of the UltraHigh Current Flow UltraHigh Surface Area ThermoCouple and Low Current FlowJunction Defeater is quite simple, It is simply an Printed Thermocouple, of an highly electropositive and highly electronegative conductors with an gold plating inbetween the two conductors to prevent chemical reactions.

The item is made by taking an Glass Plate and vapor plating an conductor such as magnesium on it, then an gold layer, then an layer of something like aluminum. The conductors are then Microetched using common microchip technology as finely as possible.

The design for what is being etched is fairly simple, you start out with an duel conductor buss on one side of the glass surface of only two conductors, such as gold and one other conductor matching one of the surface conductors in the Trimetal layer, this is connected to the Trimetal layer that is to be microetched. This in turn is connected to the other surface conductor of the Trimetal layer.

These are microetched all at once to make primary conductor busses, with smaller busses coming off these at 90 degrees and at 90 degrees to these thin busses as narrow as they can be microetched, and as close together as they can be microetched. The common gold layer is used also to carry charge off the surfaces of the Trimetal and this gold layer is then used to match to an bimetal of gold and an conductor layer of the common single element conductor used as an near equal thermal expansion coefficient between glass and conductor in common light bulbs. This is microetched at the same time, before the entire junction defeater is encased entirely in glass.

Now this design is an extremely high current flow thermocouple and two of them can be used for heating and cooling when connected together properly in series. Likewise, by connection of multiple numbers of junction defeaters in series, you can attain an voltage drop that is ideal to replace varisters.

Now, bimetal ultrahigh surface area thermocouples and Junction defeaters can also be made from any two metals that chemically combine to form intermetallic alloys.

What is claimed is:

1. What I claim as my invention is junction defeaters to match dissimilar conductors together with close to zero voltage drop.

2. What I claim as my invention is bimetal thermocouples based on any type of intermetallic alloy forming between two metals.

3. What I claim as my invention is printed circuit ultrahigh surface area thermocouples for heating and cooling with ultrahigh current capability with incredibly energy dense size efficiency.

4. What I claim as my invention is Trimetal thermocouples having an barrior metal such as gold or any other barrior metal, including double intermetallic alloy layer configurations.
